(19) United States
(12) Patent Application Publication
(10) Pub. No.: US 2020/0350444 A1
(43) Pub. Date: Nov. 5, 2020

(54) PASTE COMPOSITION FOR ELECTRODE OF SOLAR CELL, AND SOLAR CELL PRODUCED USING PASTE COMPOSITION

(71) Applicant: LS-NIKKO COPPER INC., Ulsan (KR)

(72) Inventors: Tae Hyun JUN, Seongnam (KR); In Chul KIM, Yongin (KR); Min Soo KO, Seoul (KR); Hwa Young NOH, Hwaseong (KR); Mun Seok JANG, Seoul (KR); Chung Ho KIM, Namyangju (KR); Kang Ju PARK, Seongnam (KR); Hwa Joong KIM, Seoul (KR)

(21) Appl. No.: 16/955,456

(22) PCT Filed: Oct. 18, 2018
(86) PCT No.: PCT/KR2018/012333

§ 371 Date: Jun. 18, 2020

(30) Foreign Application Priority Data
Dec. 21, 2017 (KR) 10-2017-0177057

(51) Int. Cl. H01L 31/0216; H01L 31/0224; H01B 1/22; H01B 1/16

(52) U.S. Cl. CPC H01L 31/02168; H01B 1/16; H01B 1/22; H01L 31/022425

(57) ABSTRACT

The present invention provides a paste composition for a solar cell electrode, the paste composition including a conductive metal powder, a glass fit, and an organic vehicle, wherein the conductive metal powder includes at least two surface treatment parts positioned at the outer periphery thereof, and one of the surface treatment parts is formed by silicone oil.

### CROSS-REFERENCE TO RELATED APPLICATION

The present application is a National Phase Entry into the U.S. of PCT/KR2018/012333 filed Oct. 18, 2018, which claims priority to and the benefit of Korean Patent Application No. 10-2017-0177057, filed on Dec. 21, 2017, the disclosure of which is incorporated herein by reference in its entirety.

### TECHNICAL FIELD

The present invention relates to a paste composition for an electrode of a solar cell, and a solar cell produced using the paste composition.

### BACKGROUND ART

This section provides background information related to the present disclosure which is not necessarily prior art.

A solar cell is a semiconductor device that converts solar energy into electrical energy, and generally has a p-n junction type. The basic structure of the solar cell is the same as that of a diode.

FIG. 1 illustrates a structure of a general solar cell device. The solar cell device is generally constructed using a p-type silicon semiconductor substrate having a thickness of 160 to 250 μm. An n-type impurity layer having a thickness of 0.3 to 0.6 μm is formed on a light-receiving surface side of the silicon semiconductor substrate, and an anti-reflection film and a front electrode are formed thereon. Further, a back electrode is formed on a back surface of the p-type silicon semiconductor substrate. The front electrode is formed by a method such as screen printing using a conductive paste that is formed by mixing silver-based conductive particles, a glass frit, an organic vehicle, and additives. The back electrode is formed in such a manner that an aluminum paste composition composed of an aluminum powder, a glass frit, and an organic vehicle is applied by screen printing or the like, followed by drying, and then firing at a temperature of equal to or greater than 660° C. (melting point of aluminum). During firing, aluminum diffuses into the p-type silicon semiconductor substrate, thereby forming an Al—Si alloy layer between the back electrode and the p-type silicon semiconductor substrate, and at the same time, a p+layer is formed as an impurity layer by diffusion of aluminum atoms. The presence of such a p+layer prevents recombination of electrons and obtains a back surface field (BSF) effect that improves collection efficiency of generated carriers is obtained. A back silver electrode may be further positioned under the back aluminum electrode.

Meanwhile, during firing, at the front electrode, the anti-reflection film is eroded through an oxidation-reduction reaction of glass frit powder, and conductive metal crystal grains are deposited in a form in which conductive powder crystals in the glass frit powder are deposited at the substrate interface. It is known that the deposited metal crystal grains not only serve as a bridge between the bulk front electrode and the silicon substrate, but also exhibit a tunneling effect depending on the thickness of the glass frit powder or contact due to direct adhesion to the bulk electrode.

An electrode pattern of the front electrode of the solar cell is generally obtained using a printing method such as screen printing. However, when slip properties of a paste are poor, there is a problem in that during screen printing, the paste cannot escape through a screen mesh, resulting a problem in that the electrode pattern may not be formed as designed but become uneven or nonuniform. Particularly, line breaks may occur or resistance may be greatly increased when a fine line width is realized. Therefore, slip properties of the paste are a very important factor.

### DISCLOSURE

### Technical Problem

To increase slip properties of a paste, adding silicone oil to the paste may be considered. However, in the case of the silicone oil, compatibility with an organic vehicle such as an organic solvent is poor, phase separation occurs and thus uniformity of the paste is impaired, and storage stability is problematic, making it very difficult to use the silicone oil. In order to solve this problem, there is a method of modifying by introducing a polyether group including ethyl oxide (EO) and propyl oxide (PO) groups into the silicone oil. However, this method has a problem in that slip properties may be deteriorated.

An objective of the present invention is to provide a paste composition for an electrode of a solar cell, and a high-efficiency solar cell, wherein a phase separation problem occurring in the use of silicone oil while slip properties can be significantly improved, thereby realizing a fine line width.

However, the objectives of the present invention are not limited to the above-mentioned objective, and other objectives not mentioned will be clearly understood by those skilled in the art from the following description.

### Technical Solution

In order to accomplish the above objective, the present invention provides

a paste composition for an electrode of a solar cell, the paste composition including: a conductive metal powder; a glass frit; and an organic vehicle, wherein the conductive metal powder may include at least two surface treatment parts positioned at an outer periphery thereof, and one of the surface treatment parts may be formed by silicone oil.

Further, the present invention provides a paste composition for an electrode of a solar cell, the paste composition including: a conductive metal powder; a glass frit; an organic vehicle; and silicone oil, wherein the conductive metal powder may be a primary surface-treated powder, and the silicone oil may be coated on the primary surface-treated metal powder so that phase separation from the organic vehicle may not be observed.

Further, the present invention provides a method of preparing a paste composition for an electrode of a solar cell, the method including: preparing a surface-treated conductive metal powder; and mixing the surface-treated conductive metal powder, a glass fit, and an organic vehicle, wherein the preparing the surface-treated conductive metal powder may include: forming a first surface treatment part on the conductive metal powder; and forming a second surface treatment part with silicone oil.

Further, the present invention provides a solar cell, including: a front electrode provided on a substrate; and a back electrode provided under the substrate, wherein the front electrode may be produced by applying the paste composition, followed by firing.

### Advantageous Effects

The present invention having the above constitutional features provides

a paste composition for an electrode of a solar cell, and a high-efficiency solar cell, wherein a phase separation problem occurring in the use of silicone oil while slip properties can be significantly improved, thereby realizing a fine line width. More detailed effects will be described later through examples.

### DESCRIPTION OF DRAWINGS

FIG. 1 is a schematic sectional view illustrating a general solar cell device.

FIGS. 2a(a), 2a(b), 2b(a), and 2b(b) are photographs illustrating evaluation of silicone oil phase separation of a conductive paste according to an embodiment of the present invention.

FIGS. 3 to 13 are test photographs illustrating slip properties and electrode pattern uniformity of the conductive paste according to the embodiment of the present invention.

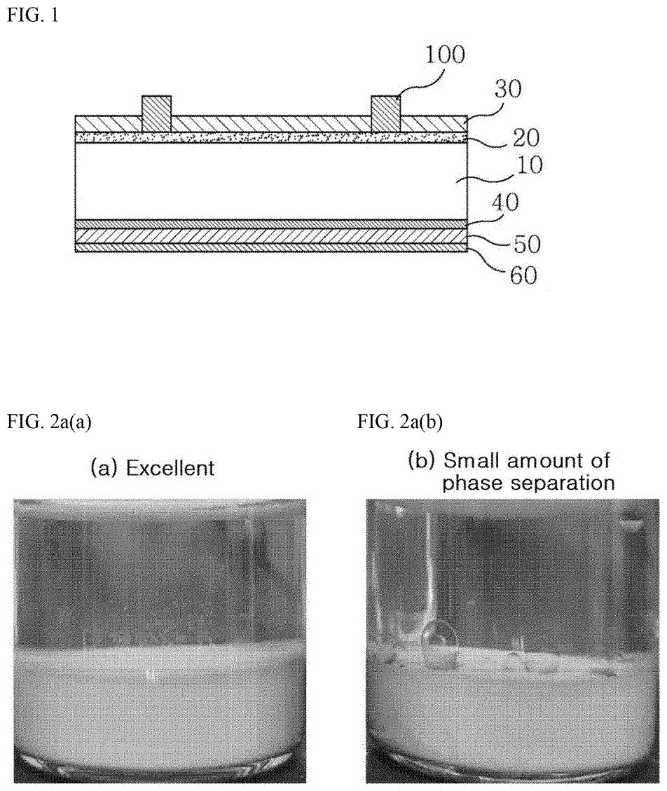

### MODE FOR INVENTION

Prior to describing the present invention in detail below, it should be understood that the terms used herein are merely intended to describe specific embodiments and are not to be construed as limiting the scope of the present invention, which is defined by the appended claims. Unless otherwise defined, all terms including technical and scientific terms used herein have the same meaning as commonly understood by one of ordinary skill in the art to which this invention belongs.

Throughout this specification and the claims, unless otherwise defined, the terms “comprise”, “comprises”, and “comprising” will be understood to imply the inclusion of a stated object, a step or groups of objects, and steps, but not the exclusion of any other objects, steps or groups of objects or steps.

Meanwhile, unless otherwise noted, various embodiments of the present invention may be combined with any other embodiments. In particular, any feature which is mentioned preferably or favorably may be combined with any other features which may be mentioned preferably or favorably.

Hereinafter, the present invention will be described in more detail through drawings and examples. Since the following description is for a specific example of the present invention, there may be conclusive and restrictive, but this is not intended to limit the scope of rights defined by the claims.

A paste composition for an electrode of a solar cell according to an embodiment of the present invention includes a conductive metal powder, a glass frit, and an organic vehicle, wherein the conductive metal powder includes a conductive metal core and at least two surface treatment parts positioned at the outer periphery of the core, and one of the surface treatment parts is formed by silicone oil.

The present inventors have found that when silicone oil is used as a conductive paste component, slip properties of the paste is improved, which improves printability and can greatly contribute to realization of a fine line width. However, the silicone oil is a material which has poor compatibility with water and poor compatibility with organic solvents, and thus is difficult to disperse uniformly. In particular, the silicone oil exhibits incompatibility with organic vehicles used in conductive pastes, and thus has great restrictions on use and has a problem of deteriorating solar cell characteristics.

Accordingly, the present inventors have significantly improved slip properties and realization of a fine line width with the use of the silicone oil as a component of a conductive paste while dramatically improving the incompatibility problem of the silicone oil, and improved solar cell characteristics.

Hereinafter, each component will be described in detail.

<Conductive Metal Powder>

As a conductive metal powder, a silver powder, copper powder, nickel powder, aluminum powder, or the like may be used. The silver powder is mainly used for a front electrode, and the aluminum powder is mainly used for a back electrode. Hereinafter, for convenience of description, a conductive metal powder will be described using the silver powder as an example. The following description can be equally applied to other metal powders.

The silver powder is preferably a pure silver powder, and in addition, a silver-coated composite powder in which a silver layer is formed on at least the surface thereof, or an alloy including silver as a main component may be used. Further, other metal powders may be mixed and used. Examples may include aluminum, gold, palladium, copper, and nickel. The silver powder may have an average particle diameter of 0.1 to 10 μm, and preferably 0.5 to 5 μm when considering ease of pasting and density during firing, and the shape thereof may be at least one of spherical, needle-like, plate-like, and amorphous. The silver powder may be used by mixing two or more powders having different average particle diameters, particle size distributions, and shapes. The amount of the silver powder is preferably 60 to 98% by weight with respect to the total weight of the paste composition for the electrode when considering electrode thickness formed during printing and linear resistance of the electrode.

The conductive metal powder may include at least two surface treatment parts. One of the surface treatment parts is formed by silicone oil. The surface of the conductive metal powder may be entirely or partially treated with the silicone oil, thereby greatly improving slip properties of the paste.

Preferably, one of the at least two surface treatment parts is formed by a fatty acid or fatty acid salt, and a the fatty acid or fatty acid salt is positioned partially or entirely between the conductive metal core and the silicone oil. On the other hand, a fatty amine may be used instead of the fatty acid or fatty acid salt. The fatty acid, fatty acid salt, fatty amine may have a carbon number in the range of 14 to 20 because the effect of the present invention may be further improved within this range. By mediation of the fatty acid, fatty acid salt, or fatty amine, compatibility of silicone oil may be further improved, thus phase separation may be prevented. Furthermore, sintering characteristics of the silver powder may be improved and resistivity of the electrode may be reduced.

Hereinafter, a description will be given of a method of primary surface treatment of a conductive metal powder with a fatty acid or fatty acid salt.

The primary surface treatment of the conductive metal powder with the fatty acid or fatty acid salt may be performed in such a manner that the conductive metal powder is dispersed in a solvent of 2 to 5 times the mass thereof, and an alcohol solution including a fatty acid or fatty acid salt may be then added and stirred, followed by filtration, washing, and drying. In this case, an alcohol solution in which 5 to 20 wt % of the fatty acid or fatty acid salt is dissolved with respect to the total weight of the solution may be used. As an alcohol, methanol, ethanol, n-propanol, benzyl alcohol, terpineol, or the like may be used, and preferably ethanol is used.

An alcohol solution including a fatty acid or fatty acid salt may be added to a solution in which the conductive metal powder is dispersed, followed by stirring at 2000 to 5000 rpm for 10 to 30 minutes using a stirrer. The fatty acid or fatty acid salt may be used in an amount of 0.1 to 1.0 parts by weight with respect to 100 parts by weight of the conductive metal powder. When the amount thereof is less than 0.1 parts by weight, a small amount of a surface treating agent may be adsorbed on the surface of the conductive metal powder, resulting in aggregation occurring between powder particles, and the effect of improving compatibility of the silicone oil may be negligible. On the other hand, when the amount thereof is greater than 1.0 part by weight, an excessive amount of surface treating agent may be adsorbed on the surface of the conductive metal powder, resulting in a problem in that electrical conductivity of a produced electrode may be deteriorated.

Examples of the fatty acid include at least one selected from the group consisting of lauric acid, myristic acid, palmitic acid, stearic acid, behenic acid, oleic acid, linolic acid, and arachidonic acid. A fatty acid salt having a carbon number of 14 to 20 is preferred, and stearic acid or oleic acid is preferably used.

The fatty acid salt includes a fatty acid salt in which the fatty acid forms a salt with calcium hydroxide, sodium hydroxide, ammonia, methylamine, dimethylamine, trimethylamine, ethylamine, diethylamine, triethylamine, ethanolamine, diethanolamine, or triethanolamine. A fatty acid salt having a carbon number of 14 to 20 is preferred, and ammonium stearate or ammonium oleate in which stearic acid or oleic acid forms a salt with ammonia water is preferably used.

Meanwhile, the conductive metal powder may be surface-treated in advance so that the surface treatment with the fatty acid or fatty acid salt is performed well, and an anionic surfactant may be used. The conductive metal powder may be dispersed in a solvent, and anionic surfactant may be then added and mixed. Preferred examples of the anionic surfactant include at least any one selected from the group consisting of aromatic alcohol phosphate, fatty alcohol phosphate, dialkyl sulfosuccinate, and polypeptide. Preferably, the fatty alcohol phosphate is included. As the solvent, water, ethanol, isopropyl alcohol, ethylene glycol hexyl ether, diethylene glycol, butyl ether propylene glycol, propyl ether, or the like may be used, and water is preferably used. In this case, 0.1 to 2 parts by weight of the anionic surfactant may be used with respect to 100 parts by weight of the conductive metal powder. When the amount thereof is less than 0.1 parts by weight, a small amount of a surface treating agent may be adsorbed on the surface of the silver powder and thus the surface treatment with the fatty acid or fatty acid salt may be insufficient. On the other hand, when the amount thereof is greater than 2 parts by weight, excessive foam may occur in a surface treatment process, resulting in poor workability, and an excessive amount of the surface treating agent may be adsorbed on the surface of the silver powder, resulting in a problem in that electrical conductivity of a produced electrode may be deteriorated.

Next, the primary surface treatment of the conductive metal powder with a fatty amine instead of the fatty acid or fatty acid salt will be described.

The primary surface treatment of the conductive metal powder with the fatty amine may be performed in such a manner that the conductive metal powder is added to an alcohol solution including a fatty amine at a concentration of 10 to 15 wt %, followed by stirring. As an alcohol, methanol, ethanol, n-propanol, benzyl alcohol, or terpineol may be used, and ethanol is preferably used.

The fatty amine may be mixed in an amount of 0.1 to 1.0 parts by weight with respect to 100 parts by weight of the conductive metal powder. When the fatty amine is mixed in an amount less than 0.1 part by weight, the surface treatment amount thereof may be insufficient, resulting in a problem in that the effect thereof may not be exhibited well. On the other hand, the fatty amine is mixed in an amount greater than 1.0 part by weight, there is a problem in that a residual surface treating agent may deteriorate electrical characteristics.

The fatty amine includes, for example, triethylamine, heptylamine, octadecylamine, hexadecylainine, decylamine, octylamine, didecylamine, or trioctylamine, and a fatty amine having a carbon number of 14 to 20 is preferably used. When an alkyl amine having a carbon number of less than 14, there is a problem in that a desired effect may not be exhibited. On the other hand, when an alkyl amine having a carbon number of greater than 20, this alkyl amine may be difficult to dissolve in a solvent, and there is a problem in that the surface treatment may not be performed well.

Meanwhile, the conductive metal powder may be surface-treated in advance so that the surface treatment with the fatty amine is performed well, and a surface treating agent may be used in an amount of 0.1 to 1.0 parts by weight with respect to 100 parts by weight of the conductive metal powder. When the amount thereof is less than 0.1 part by weight, there is a problem in that the surface treatment may not be completely performed. On the other hand, when the amount thereof is greater than 1.0 part by weight, there is a problem in that residual organic matter may be generated thereby affecting paste characteristics or affecting electrical characteristics. Examples of the surface treating agent include alkyl sulfate, ethoxylated alkyl sulfate, alkyl glyceryl ether sulfonate, alkyl ethoxy ether sulfonate, acyl methyl taurate, fatty acyl glycinate, alkyl ethoxy carboxylate, acyl glutamate, acyl isethionate, alkyl sulfosuccinate, alkyl ethoxy sulfosuccinate, alkyl phosphate ester, acyl sarcosinate, acyl aspartate, alkoxy acyl amide carboxylate, acyl ethylenediamine triacetate, acyl hydroxyethyl isethionate, and mixtures thereof. Preferably, a phosphate-based material is used, and more preferably, a phosphate ester is used.

The conductive metal powder that is primary surface-treated with the fatty acid, fatty acid salt, or fatty amine is subjected to a secondary surface treatment with silicone oil. The type of the silicone oil is not limited, but may be polysiloxane such as polydimethylsiloxane, and an unmodified polysiloxane oil is preferably used when considering slip properties.

A surface treatment method is not limited, but preferably is performed in such a manner that the primary surface-treated conductive metal powder is mixed with an organic solvent, and the silicone oil is then added, followed by stirring to form a second surface treatment part on the conductive metal powder. A final surface treatment amount of the silicone oil is not limited, but may be 0.1 to 5 parts by weight with respect to 100 parts by weight of the conductive metal powder, and preferably 0.5 to 2 parts by weight. The amount thereof is less than the above range, slip properties may be poor, and when the amount thereof is greater than the above range, electrical characteristics may be deteriorated.

The organic solvent may be an organic solvent used for a conductive paste. The organic solvent may be removed after the surface treatment with the silicone oil, thereby obtaining a surface-treated conductive metal powder.

On the other hand, each of the primary surface-treated conductive metal powder and the organic solvent used for the conductive paste may be used in a paste addition amount, mixed, and surface-treated by adding silicone oil, and other components of a paste, such as glass frit and organic vehicle may be added without removing the organic solvent, thereby preparing a conductive paste.

<Organic Vehicle>

An organic vehicle is not limited, but may include an organic binder, a solvent, and the like. The use of the solvent may be omitted in some cases. The organic vehicle is not limited, but is preferably included in an amount of 1 to 10% by weight with respect to the total weight of the paste composition for the electrode.

The organic binder used in the paste composition for the electrode is not limited, but examples thereof may include a cellulose ester compound such as cellulose acetate, cellulose acetate butyrate, and the like; a cellulose ether compound such as ethyl cellulose, methyl cellulose, hydroxy propyl cellulose, hydroxy ethyl cellulose, hydroxy propyl methyl cellulose, hydroxy ethyl methyl cellulose, and the like; an acrylic compound such as polyacrylamide, polymethacrylate, polymethyl methacrylate, polyethyl methacrylate, and the like; and a vinyl compound such as polyvinyl butyral, polyvinyl acetate, polyvinyl alcohol, and the like. At least one of the binders may be selected and used.

As a solvent used for dilution of the composition, at least one of compounds selected from the group consisting of alpha-terpineol, texanol, dioctyl phthalate, dibutyl phthalate, cyclohexane, hexane, toluene, benzyl alcohol, dioxane, diethylene glycol, ethylene glycol monobutyl ether, ethylene glycol monobutyl ether acetate, diethylene glycol mono butyl ether, diethylene glycol mono butyl ether acetate, and the like is preferably used.

<Glass Frit>

A glass frit used is not limited. A leaded glass fit as well as a lead-free glass fit may be used. The composition, particle diameter, and shape of the glass frit are not particularly limited. Preferably, as the components and amounts of the glass frit, on an oxide basis, 5 to 29 mol % of PbO, 20 to 34 mol % of TeO₂, 3 to 20 mol % of Bi₂O₃, equal to or less than 20 mol % of Sift), and equal to or less than 10 mol % of B₂O₃ are included, and an alkali metal (Li, Na, K, and the like) and an alkaline earth metal (Ca, Mg, and the like) are included in an amount of 10 to 20 mol %. By organically combining the amount of each component, it is possible to prevent an increase in the line width of an electrode, ensuring excellent contact resistance at high sheet resistance, and ensuring excellent short-circuit current characteristics.

In particular, when the amount of PbO is too high, there is a problem in that it may be difficult to ensure eco-friendliness, and in that viscosity may become too low during melting and thus the line width of the electrode may increase during firing. Therefore, PbO is preferably included within the above range in the glass frit.

Meanwhile, the average particle diameter of the glass fit is not limited, but may fall within the range of 0.5 to 10 gill, and the glass frit may be used by mixing different types of particles having different average particle diameters. Preferably, at least one type of glass fit has an average particle diameter D50 of equal to or greater than 2 μm and equal to or less than 10 μm. This makes it possible to ensure excellent reactivity during firing, and in particular, minimize damage to an n-layer at a high temperature, improve adhesion, and ensure excellent open-circuit voltage (Voc). It is also possible to reduce an increase in the line width of the electrode during firing. Further, the glass transition temperature Tg of the glass frit having an average particle diameter of equal to or greater than 2 on and equal to or less than 10 μm is preferably less than 300° C. Since particles having a relatively large particle size are used, a problem such as uneven melting during firing may be prevented by lowering the glass transition temperature.

The amount of the glass frit is preferably 1 to 15% by weight with respect to the total weight of the conductive paste composition. When the amount thereof is less than 1% by weight, there is a possibility that electrical resistivity may increase due to incomplete firing. On the other hand, when the amount thereof is greater than 15% by weight, there is a possibility that electrical resistivity may increase due to too many glass components in a fired body of the glass powder.

<Other Additives>

The conductive paste composition according to the present invention may further include, as needed, an additive generally known, for example, a dispersant, plasticizer, a viscosity modifier, a surfactant, an oxidizing agent, a metal oxide, a metal organic compound, and the like.

The present invention also provides a method of forming an electrode of a solar cell, characterized in that the paste for the electrode of the solar cell is coated on a substrate, dried, and fired, and provides a solar cell electrode produced by the method. In the method of forming the electrode of the solar cell according to the present invention, except that the paste for the electrode of the solar cell is used, the substrate, printing, drying, and firing can be implemented by using methods generally used in manufacturing of solar cells. In an example, the substrate may be a silicon wafer, the electrode produced from the paste according to the present invention may be a finger electrode or a busbar electrode of the front electrode, the printing may be screen printing or offset printing, the drying may be performed at 90 to 350° C., and the firing may be performed at 600 to 950° C. Preferably, the firing is performed at 800 to 950° C., more preferably, high temperature/high speed firing is performed at 850 to 900° C. for 5 seconds to 1 minute, and the printing is performed to a thickness of 20 to 60 μm. Specific examples include the structure of a solar cell and a method of manufacturing the same disclosed in Korean Patent Application Publication Nos. 10-2006-0108550 and 10-2006-0127813, and Japanese Patent Application Publication Nos. 2001-202822 and 2003-133567.

A description will be given in more detail through the following examples.

### Preparation Example 1-1

2 L of de-mineralized water (DMW) and 500 g of a prepared silver powder were placed in a 5 L beaker, and then the silver powder was dispersed at 4000 rpm for 20 minutes using a homo-mixer, thereby preparing a silver slurry. Meanwhile, 30 ml of pure water was placed in a 50 ml beaker, and 5 g of PS-810E (fatty alcohol phosphate, produced by ADEKA Corp.) was added, followed by stirring for 10 minutes with ultrasonic waves, thereby preparing a coating solution. The coating solution was added to the silver slurry, followed by stirring at 4000 rpm for 20 minutes to surface-treat the silver powder, and then a resulting silver powder was further washed with pure water by means of centrifugation, thereby preparing a silver powder.

Thereafter, the prepared silver powder was dispersed in 2 L of pure water, an ammonium stearate solution dissolved in 15 ml ethanol was added, followed by stirring at 4000 rpm for 20 minutes to surface-treat the silver powder, and then a resulting silver powder was washed in the same manner as above, thereby preparing a surface-treated silver powder.

Thereafter, hot air drying was performed at 80° C. for 12 hours, and disintegration was performed using a jet mill, thereby completing a silver powder.

### Preparation Example 1-2

100 g of a silver powder and 0.5 g of anionic surfactant PS-810E (produced by ADEKA Corp.) were added to 400 ml pure water, followed by stirring using a homo-mixer (produced by K&S company, for lab use) at 3000 rpm for 20 minutes to disperse the silver powder. 2.7 g of octadecylamine ethanol solution (octadecylamine amount of 11.25% by weight) was added to a solution in which the silver powder was dispersed, followed by stirring for 20 minutes. Thereafter, the stirring was stopped, a mixed solution was filtered using a centrifuge, and then a filter medium was washed with pure water, followed by drying at 70° C. for 12 hours, thereby obtaining a primary surface-treated silver powder. This silver powder was subjected to grinding in a food mixer and disintegration in a jet mill.

### Preparation Example 1-3

The procedure in this example was performed in the same manner as in Preparation Example 1-1, except that stearic acid was used instead of ammonium stearate.

### Preparation Example 1-4

500 g of silver powder was dispersed in 2 L of pure water, a stearic acid solution dissolved in 15 ml ethanol was added, followed by stirring at 4000 rpm for 20 minutes to surface-treat the silver powder, and then a resulting silver powder was washed in the same manner as above, thereby preparing a surface-treated silver powder. Thereafter, hot air drying was performed at 80° C. for 12 hours, and disintegration was performed using a jet mill, thereby completing a silver powder.

### Preparation Example 1-5

100 g of a silver powder was dispersed in 400 ml pure water, and then 2.7 g of an octadecylamine ethanol solution (octadecylamine amount of 11.25% by weight) was added, followed by stirring for 20 minutes. Thereafter, the stirring was stopped, a mixed solution was filtered using a centrifuge, and then a filter medium was washed with pure water, followed by drying at 70° C. for 12 hours, thereby obtaining a primary surface-treated silver powder. This silver powder was subjected to grinding in a food mixer and disintegration in a jet-mill.

### Preparation Example 1-6

The procedure in this example was performed in the same manner as in Preparation Example 1-1, except that lauric acid was used instead of stearic acid.

### Preparation Example 1-7

The procedure in this example was performed in the same manner as in Preparation Example 1-2, except that decylamine was used instead of octadecylamine.

### Preparation Example 1-8

The silver powder without surface treatment in Preparation Example 1 was used.

### Preparation Example 2-1

100 g of the primary surface-treated silver powder prepared in Preparation Example 1-1 was mixed with 400 ml of alcohol, 2 g of silicone oil was added, followed by stirring for 10 minutes, and then alcohol was removed, thereby preparing a silver powder secondary surface-treated with silicone oil.

### Preparation Example 2-2

The procedure in this example was performed in the same manner as in Preparation Example 2-1, except that the first surface-treated silver powder prepared in Preparation Example 1-2 was used instead of Preparation Example 1-1, thereby preparing a silver powder secondary surface-treated with silicone oil.

### Preparation Example 2-3

The procedure in this example was performed in the same manner as in Preparation Example 2-1, except that the first surface-treated silver powder prepared in Preparation Example 1-3 was used instead of Preparation Example 1-1, thereby preparing a silver powder secondary surface-treated with silicone oil.

### Preparation Example 2-4

The procedure in this example was performed in the same manner as in Preparation Example 2-1, except that the first surface-treated silver powder prepared in Preparation Example 1-4 was used instead of Preparation Example 1-1, thereby preparing a silver powder secondary surface-treated with silicone oil.

### Preparation Example 2-5

The procedure in this example was performed in the same manner as in Preparation Example 2-1, except that the first surface-treated silver powder prepared in Preparation Example 1-5 was used instead of Preparation Example 1-1, thereby preparing a silver powder secondary surface-treated with silicone oil.

### Preparation Example 2-6

The procedure in this example was performed in the same manner as in Preparation Example 2-1, except that the first surface-treated silver powder prepared in Preparation Example 1-6 was used instead of Preparation Example 1-1, thereby preparing a silver powder secondary surface-treated with silicone oil.

### Preparation Example 2-7

The procedure in this example was performed in the same manner as in Preparation Example 2-1, except that the first surface-treated silver powder prepared in Preparation Example 1-7 was used instead of Preparation Example 1-1, thereby preparing a silver powder secondary surface-treated with silicone oil.

### Preparation Example 2-8

The procedure in this example was performed in the same manner as in Preparation Example 2-1, except that the silver powder without surface treatment in Preparation Example 1-8 was used instead of Preparation Example 1-1, thereby preparing a silver powder surface-treated with silicone oil.

### Preparation Example 3-1

With the composition as illustrated in Table 1 below, a binder, a dispersant, a leveling agent, a glass frit, and the like were added and dispersed using a three-roll mill, mixed with the silver powder secondary surface-treated with the silicone oil, which was prepared in Preparation Example 2-1, and then dispersed using a three-roll mill. Thereafter, degassing under reduced pressure was performed to prepare a conductive paste.

TABLE 1

| Classification | Preparation Example 3-1 |
|---|---|
| EC | 0.5 |
| EFKA-4330 | 0.5 |
| BYK180 | 0.7 |
| Texanol | 2.5 |
| Butyl cellosolve | 2.5 |
| Thixatrol ST | 0.3 |
| Dimethyl adipate | 1.5 |
| Silver powder | 89.5 |
| Glass frit | 2 |

### Preparation Example 3-2

The procedure in this example was performed in the same manner as in Preparation Example 3-1, except that the silver powder secondary surface-treated with the silicone oil, which was prepared in Preparation Example 2-2, was used instead of Preparation Example 2-1, thereby preparing a conductive paste.

### Preparation Example 3-3

The procedure in this example was performed in the same manner as in Preparation Example 3-1, except that the silver powder secondary surface-treated with the silicone oil, which was prepared in Preparation Example 2-3, was used instead of Preparation Example 2-1, thereby preparing a conductive paste.

### Preparation Example 3-4

The procedure in this example was performed in the same manner as in Preparation Example 3-1, except that the silver powder secondary surface-treated with the silicone oil, which was prepared in Preparation Example 2-4, was used instead of Preparation Example 2-1, thereby preparing a conductive paste.

### Preparation Example 3-5

The procedure in this example was performed in the same manner as in Preparation Example 3-1, except that the silver powder secondary surface-treated with the silicone oil, which was prepared in Preparation Example 2-5, was used instead of Preparation Example 2-1, thereby preparing a conductive paste.

### Preparation Example 3-6

The procedure in this example was performed in the same manner as in Preparation Example 3-1, except that the silver powder secondary surface-treated with the silicone oil, which was prepared in Preparation Example 2-6, was used instead of Preparation Example 2-1, thereby preparing a conductive paste.

### Preparation Example 3-7

The procedure in this example was performed in the same manner as in Preparation Example 3-1, except that the silver powder secondary surface-treated with the silicone oil, which was prepared in Preparation Example 2-7, was used instead of Preparation Example 2-1, thereby preparing a conductive paste.

### Preparation Example 3-8

The procedure in this example was performed in the same manner as in Preparation Example 3-1, except that the silver powder secondary surface-treated with the silicone oil, which was prepared in Preparation Example 2-8, was used instead of Preparation Example 2-1, thereby preparing a conductive paste.

### Preparation Example 3-9

The procedure in this example was performed in the same manner as in Preparation Example 3-1, except that the silver powder only primary surface-treated, which was prepared in Preparation Example 1-1, was used instead of Preparation Example 2-1, and that a paste was prepared by separately adding 2 parts by weight of silicone oil with respect to 100 parts by weight of silver, thereby preparing a conductive paste.

### Preparation Example 3-10

The procedure in this example was performed in the same manner as in Preparation Example 3-1, except that the silver powder without surface treatment, which was prepared in Preparation Example 1-8, was used instead of Preparation Example 2-1, and that a paste was prepared by separately adding 2 parts by weight of silicone oil with respect to 100 parts by weight of silver, thereby preparing a conductive paste.

### Preparation Example 3-11

The procedure in this example was performed in the same manner as in Preparation Example 3-1, except that the silver powder without surface treatment, which was prepared in Preparation Example 1-8, was used instead of Preparation Example 2-1, thereby preparing a conductive paste.

### Test Example 1

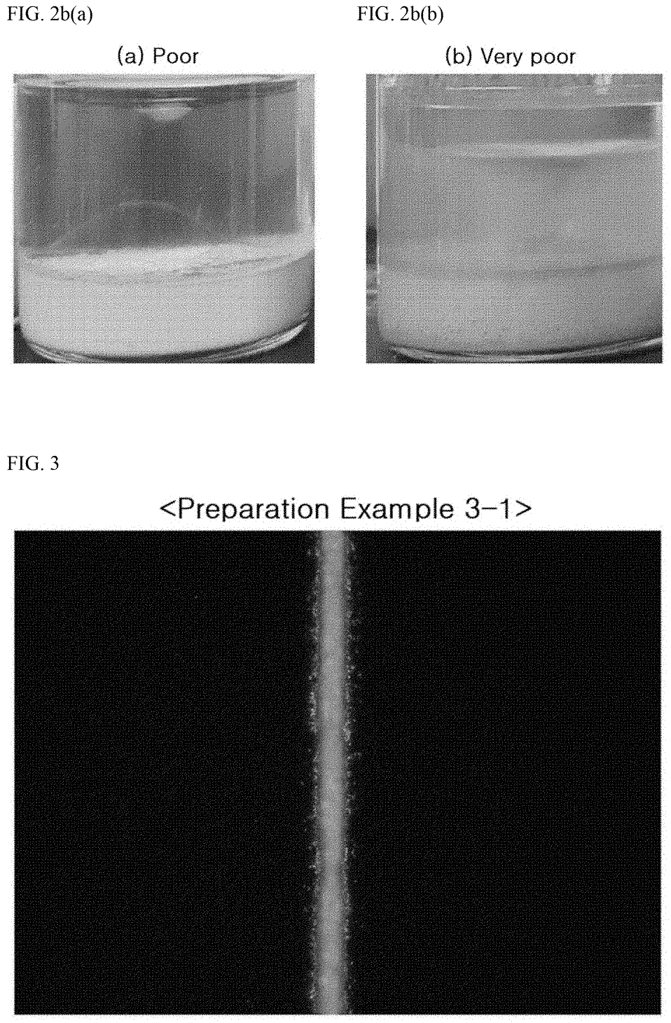

10 g of the conductive paste prepared in each of Preparation Examples 3-1 to 3-10 and 8 g of ethanol were mixed using a vertex mixer at room temperature for 5 minutes and then allowed to stand for 30 minutes to visually observe phase separation of silicone oil and ethanol A phase-separated silicone oil was separated to measure the amount of phase separation of the silicone oil, and the results are illustrated in FIGS. 2a(a), 2a(b), 2b(a), and 2b(b). Evaluation was made according to criteria of FIGS. 2a(a), 2a(b), 2b(a), and 2b(b), and the results are illustrated in Table 2 below (FIG. 2a(a) is a case where there is no amount of phase separation of the silicone oil or the amount of phase separation is equal to or less than 5% of the total amount of the silicone oil, FIG. 2a(b) is a case where the amount of a phase separation of the silicone oil is greater than 5% and equal to or less than 15%, FIG. 2b(a) is a case where the amount of phase separation of the silicone oil is greater than 15% and equal to or less than 50%, and FIG. 2b(b) is a case where the amount of phase separation of the silicone oil is greater than 50%).

TABLE 2

| Preparation Example | Phase separation observation results |
|---|---|
| Preparation Example 3-1 | Excellent |
| Preparation Example 3-2 | Excellent |
| Preparation Example 3-3 | Excellent |
| Preparation Example 3-4 | Excellent |
| Preparation Example 3-5 | Excellent |
| Preparation Example 3-6 | Small amount of phase separation |
| Preparation Example 3-7 | Small amount of phase separation |
| Preparation Example 3-8 | Poor |
| Preparation Example 3-9 | Poor |
| Preparation Example 3-10 | Very poor |

As can be seen from the results, in Preparation Examples 3-1 to 3-5, the silicone oil was in good contact with the conductive metal powder, so that phase separation was not observed or the amount of phase separation was equal to or less than 5%. In Preparation Examples 3-6 to 3-7, phase separation was slightly observed, and the amount of phase separation of the silicone oil was greater than 5% and equal to or less than 15%. In Preparation Example 3-8, a significant amount of phase separation was observed due to a weak bonding force between the silicone oil and the conductive metal since the primary surface treatment was not performed. In Preparation Example 3-9, a significant amount of phase separation was observed since the silicone oil was used as a simple additive for the paste. In Preparation Example 3-10, complete phase separation was observed, which is very poor. This phase separation phenomenon may cause unevenness of the paste and slip properties may not be uniform, which may be a significant problem in realizing fine patterns.

### Test Example 2

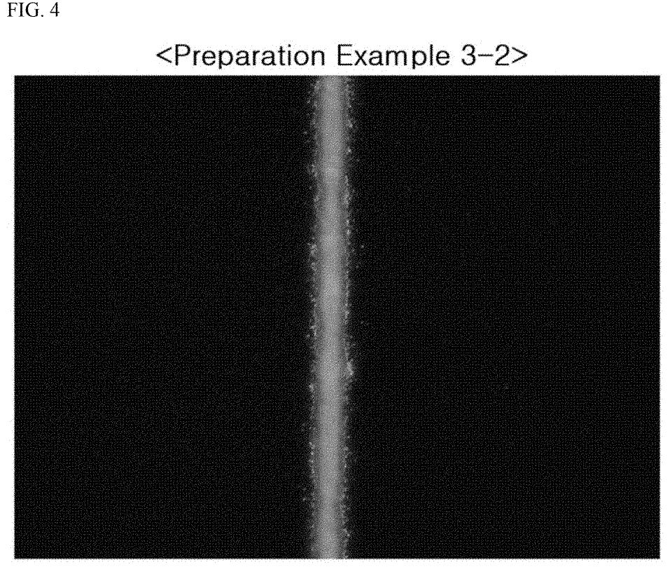

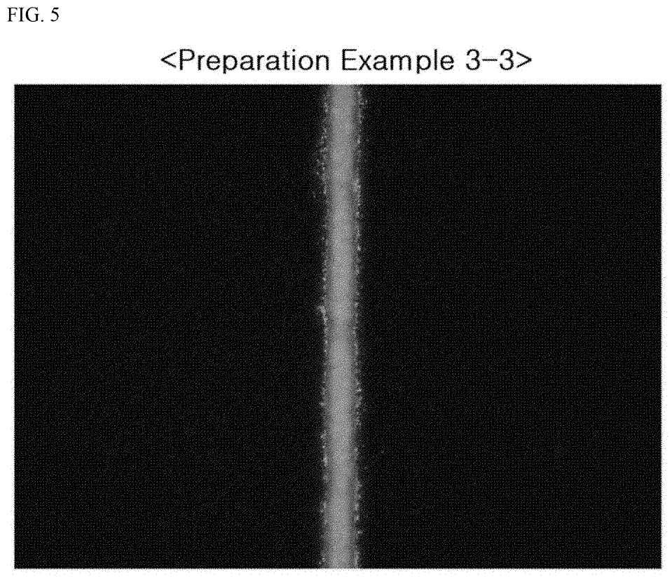

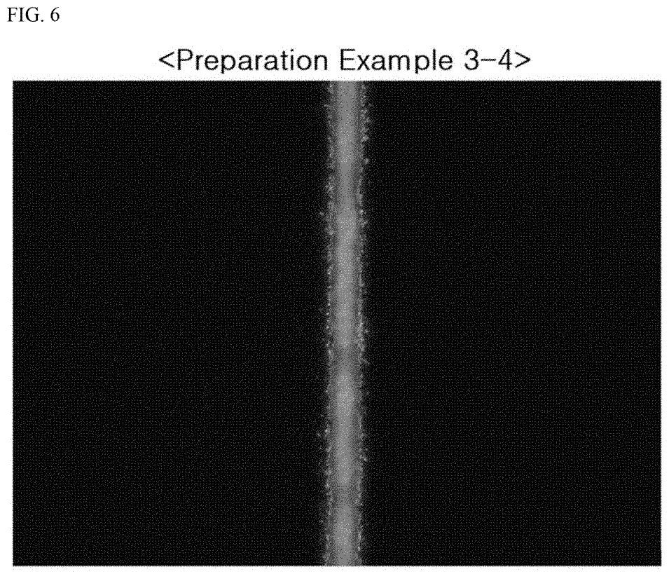

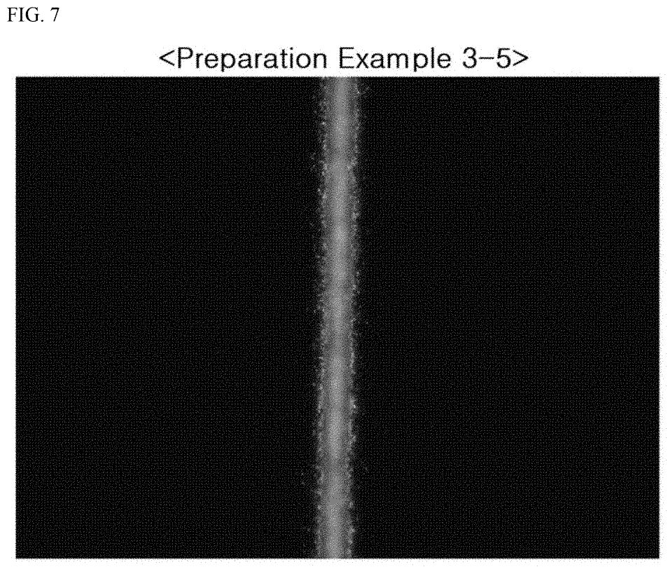

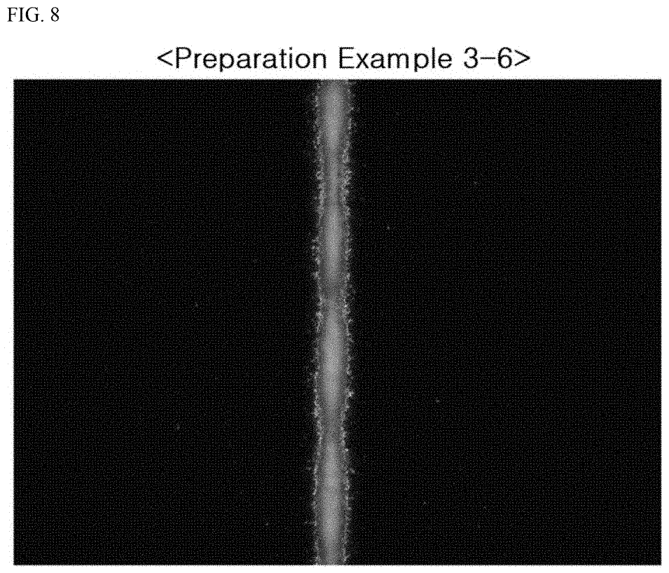

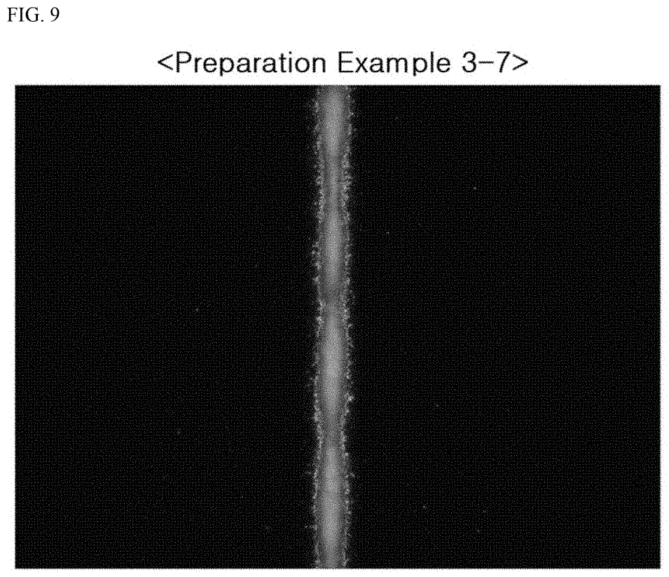

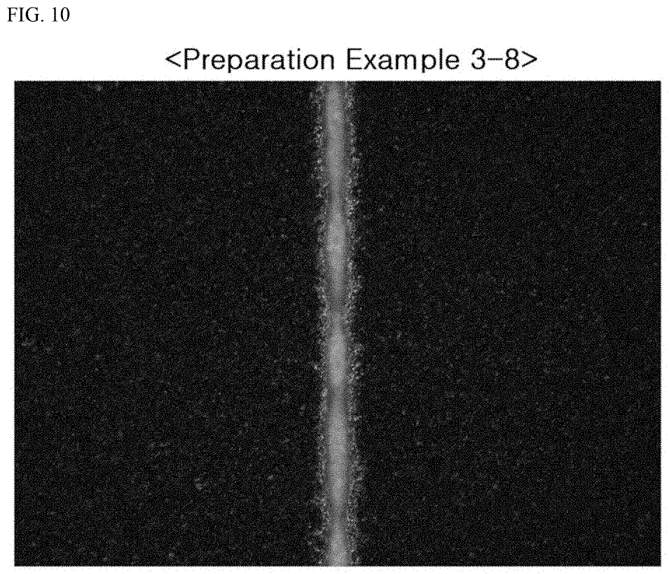

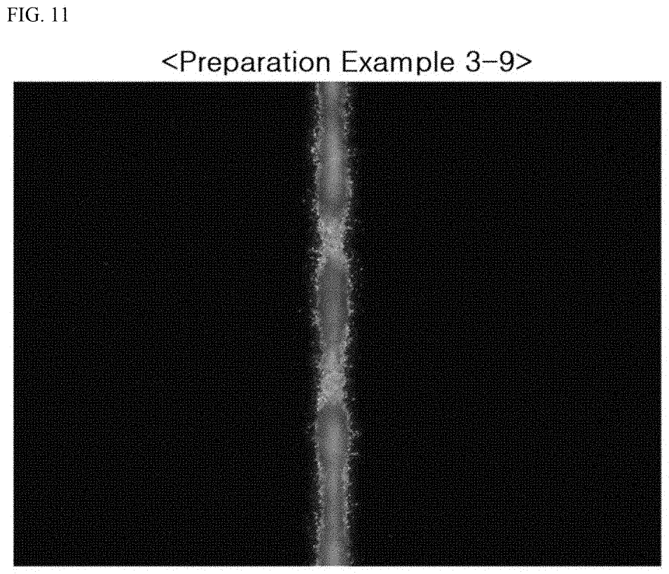

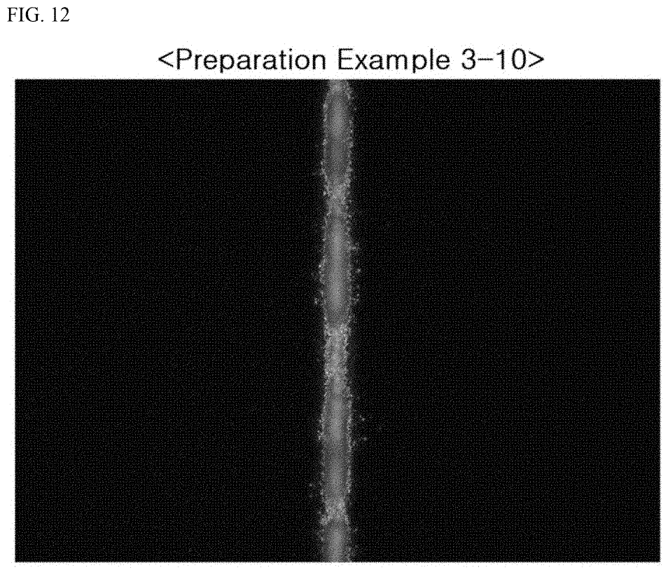

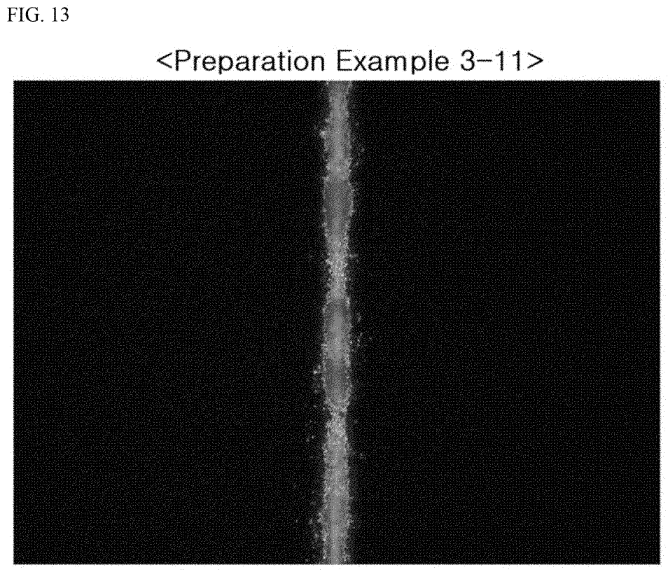

The conductive paste prepared in each of Preparation Examples 3-1 to 3-11 was pattern-printed on a front surface of a silicon wafer by screen printing using a 35 μm mesh, and dried at 200 to 350° C. for 20 to 30 seconds using a belt-type drying furnace. Then, firing was performed at 500 to 900° C. for 20 to 30 seconds using a belt-type firing furnace. Thereafter, the shape of electrode patterns was evaluated by SEM, and the results are illustrated in FIGS. 3 to 13.

In preparation Examples 3-1 to 3-3, uniformity of the electrode patterns, in particular, uniformity of pattern outlines were remarkably excellent. On the other hand, in Preparation Examples 3-6 and 3-7, uniformity of patterns was normal, and in Preparation Examples 3-8 to 3-11, there was a problem in the uniformity of patterns to such an extent that it was impossible to realize fine patterns. This is considered to be caused because slip properties of the paste are significantly deteriorated.

Since the above description is an example to help the understanding of the present invention, changes, substitutions, modifications, omissions, and the like of configurations that can be applied within the scope of the technical spirit of the present invention belong to the scope of the present invention as defined by the claims.

### DESCRIPTION OF THE REFERENCE NUMERALS IN THE DRAWINGS

10: p-type silicon semiconductor substrate
20: n-type impurity layer
30: anti-reflection film
40: p+layer (BSF: back surface field)
50: back aluminum electrode
60: back silver electrode
100: front electrode

1. A paste composition for an electrode of a solar cell, the paste composition comprising:
a conductive metal powder;
a glass frit; and
an organic vehicle,
wherein the conductive metal powder comprises at least two surface treatment parts positioned at an outer periphery thereof, and one of the surface treatment parts is formed by silicone oil.

2. The paste composition of claim 1, wherein the silicone oil and the organic vehicle are mutually incompatible.

3. The paste composition of claim 1, wherein one of the at least two surface treatment parts is formed by a fatty acid or fatty acid salt, and the fatty acid or fatty acid salt is positioned partially or entirely between the conductive metal powder and the silicone oil.

4. The paste composition of claim 3, wherein the fatty acid or fatty acid salt has a carbon number in a range of 14 to 20.

5. The paste composition of claim 3, wherein a surface treatment part that comprises at least any one selected from the group consisting of aromatic alcohol phosphate, fatty alcohol phosphate, dialkyl sulfosuccinate, and polypeptide is further included between the fatty acid or fatty acid salt and the conductive metal powder.

6. The paste composition of claim 1, wherein one of the at least two surface treatment parts is formed by a fatty amine, and the fatty amine is positioned partially or entirely between the conductive metal powder and the silicone oil.

7. The paste composition of claim 6, wherein the fatty amine has a carbon number in a range of 14 to 20.

8. The paste composition of claim 6, wherein a surface treatment part that comprises alkyl sulfate, ethoxylated alkyl sulfate, alkyl glyceryl ether sulfonate, alkyl ethoxy ether sulfonate, acyl methyl taurate, fatty acyl glycinate, alkyl ethoxy carboxylate, acyl glutamate, acyl isethionate, alkyl sulfosuccinate, alkyl ethoxy sulfosuccinate, alkyl phosphate ester, acyl sarcosinate, acyl aspartate, alkoxy acyl amide carboxylate, acyl ethylenediamine triacetate, acyl hydroxyethyl isethionate, and mixtures thereof is further included between the fatty amine and a core.

9. The paste composition of claim 1, wherein the silicone oil is included in an amount of 0.1 to 2% by weight.

10. A paste composition for an electrode of a solar cell, the paste composition comprising:
a conductive metal powder;
a glass frit;
an organic vehicle; and
silicone oil,
wherein the conductive metal powder is a primary surface-treated powder, and the silicone oil is coated on the primary surface-treated metal powder so that phase separation from the organic vehicle is not observed.

11. The paste composition of claim 10, wherein when 10 g of the paste composition and 8 g of ethanol are mixed using a vertex mixer at room temperature for 5 minutes and then allowed to stand for 30 minutes, phase separation of the silicone oil and ethanol is not observed, or an amount of phase separation is equal to or less than 5% by weight of a total amount of the silicone oil.

12. A method of preparing a paste composition for an electrode of a solar cell, the method comprising:
preparing a surface-treated conductive metal powder; and
mixing the surface-treated conductive metal powder, a glass frit, and an organic vehicle,
wherein the preparing the surface-treated conductive metal powder comprises:
forming a first surface treatment part on the conductive metal powder; and
forming a second surface treatment part with silicone oil.

13. The method of claim 12, wherein the first surface treatment part comprises a fatty acid, a fatty acid salt, or a fatty amine having a carbon number in a range of 14 to 20.

14. The method of claim 12, wherein the forming the second surface treatment part with the silicone oil is performed by mixing the conductive metal powder having the first surface treatment part formed with an organic solvent, and then adding the silicone oil to form the second surface treatment part.

15. A solar cell, comprising:
a front electrode provided on a substrate; and
a back electrode provided under the substrate,
wherein the front electrode is produced by applying the paste composition of claim 1, followed by firing.
